(19) United States
(12) Patent Application Publication
(10) Pub. No.: US 2008/0264614 A1
(43) Pub. Date: Oct. 30, 2008

(54) Cooling components in electronic devices

(76) Inventor: Thomas H. Szolyga, Saratoga, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/796,422

(22) Filed: Apr. 27, 2007

(51) Int. Cl. F28D 15/00; H05K 7/20

(52) U.S. Cl. 165/104.33; 361/702

(57) ABSTRACT

Various embodiments are directed to cooling heat generating components. In one embodiment, a method cools a heat generating component in an electronic device below an ambient temperature to produce condensation. Heat is transferred from the heat generating component to a thermal dissipation device, and the condensation is dispensed onto a thermal dissipation device to cool the thermal dissipation device.

### BACKGROUND

Some electronic devices utilize several printed circuit boards with many different electronic components interconnected to the circuit boards. As these electronic devices decrease in size and increase in performance, heat dissipation becomes increasingly important.

Circuit boards often include a plurality of heat-generating devices that need to be cooled in order to operate within a specified operating temperature. If the heat-generating devices are closely packed together, then heat from one device can affect the performance of an adjacent device. Further, if these heat-generating devices are not sufficiently cooled, then the devices can exhibit a decrease in performance or even permanently fail.

### BRIEF DESCRIPTION OF THE DRAWINGS

FIG. 1 is flow diagram of a method for cooling heat generating components in accordance with an exemplary embodiment.

FIG. 2A is a diagram of a system for cooling heat generating components in accordance with an exemplary embodiment.

FIG. 2B is a top view of a printed circuit board of FIG. 2A in accordance with an exemplary embodiment.

FIG. 3 is a diagram of an electronic device in accordance with an exemplary embodiment.

FIG. 4 is a diagram of another electronic device in accordance with an exemplary embodiment.

### DETAILED DESCRIPTION

Exemplary embodiments are directed to systems, methods, and apparatus for cooling heat generating components in electronic devices and systems. In one embodiment, the heat generating components are cooled to a temperature that is below an ambient temperature surrounding the heat generating components. Cooling below ambient temperature may create condensation if a device is cooled below the dew point. The condensation is collected and then distributed to a thermal dissipation device being used to remove heat from the heat generating components. As moist air passes over the thermal dissipation device, heat is exchanged from the thermal dissipation device to the air. The moisture and heated air are then evacuated.

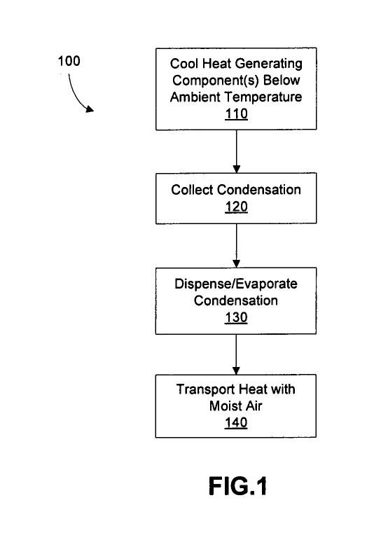

FIG. 1 is a flow diagram of a method 100 for cooling heat generating components. According to block 1 10, the heat generating components are cooled at or below ambient temperature. In doing so, some parts of the system are cooled below dew point. As used herein, the term “dew point” means a temperature at which air is cooled so water vapor condenses into water or dew.

According to block 120, condensation or dew is collected. As used herein, the term “dew” means water or droplets that form on a surface of an object. When an object radiates heat to cool, atmospheric moisture condenses at a rate greater than that which it can evaporate. This condensation results in the formation of water droplets. In one embodiment, the condensation or dew collects on an object adjacent the heat generating components. By way of example, the object collecting the dew is a condensation collector.

According to block 130, the condensation is evaporated and dispensed through moist air. In one embodiment, the condensation is vaporized or atomized and distributed via airflow to a thermal dissipation device. The thermal dissipation device is thermally coupled to the heat generating components. Heat is transferred from the heat generating components to the thermal dissipation device.

According to block 140, heat is transported with moist air. The vaporized or atomized air is forced over or at the thermal dissipation device. This air includes moisture collected from the thermal dissipation device. As the moist air contacts the thermal dissipation device, the air is heated. In one embodiment, heat is exchanged from the thermal dissipation device to the moist air as water evaporates from the thermal dissipation device. This heated and moist air, in turn, is evacuated or transported away from the thermal dissipation device and heat generating components.

In one embodiment, increased efficiency of the cooling process occurs by virtue of re-use of the condensation. Condensation is produced as the thermal dissipation device(s) cool the heat generating components. The more the heat generating components are cooled, the more condensation is produced. More condensation, in turn, produces more available liquid to be dispensed (example, sprayed or ejected) onto the thermal dissipation device. More liquid, in turn, produces more thermal capacity in the air for heat to exchange from the thermal dissipation device to the liquid. This increased capacity makes it possible to conduct more heat from fins of the thermal dissipation device to the airflow and carry more heat out of the system. Efficiency of the system then increases as more heat is conducted away from the heat generating components.

By directing condensation onto the thermal dissipation device, effective heat transfer occurs. First, the liquid evaporates and efficiently removes heat through a phase change. Second, the liquid vapor increases the density of the air flowing across the thermal dissipation device or heat sink. This airflow increases the amount of heat being removed from the heat generating components and electronic device.

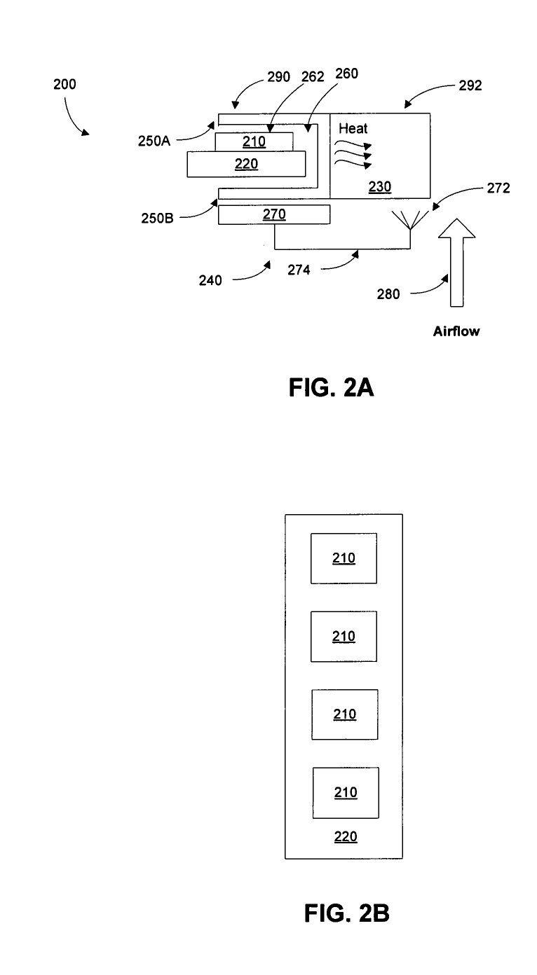

FIG. 2A shows a side view of an electrical system 200 for cooling heat generating components in accordance with an exemplary embodiment. The system generally includes plural heat generating components 210, a printed circuit board 220, one or more thermal dissipation devices 230, and a fluid dispenser 240. As shown in FIG. 2B, the printed circuit board 220 includes a plurality of heat generating components 210 situated on one side of the board.

The thermal dissipation device 230 includes two extensions 250A, 250B that form a U-shaped cavity 260 for receiving the printed circuit board 220 and heat generating components 210. By way of example, extension 250A is adjacent a first side of the printed circuit board 220, and extension 250B is adjacent a second side of the printed circuit board 220. In one embodiment, the extension 250A abuts a first surface 262 of the heat generating components 210. Thermal grease may be provided between the extension 250A and this first surface. Extension 250B is oppositely disposed and parallel with extension 250A.

In one embodiment, the thermal dissipation device 230 includes an electrical device (such as a heat pump or a Peltier device) that cools at least part of the thermal dissipation device 230 and/or the heat generating components 210 to a temperature that is at or below ambient or surrounding temperature. Heat from the heat generating components 210 transfers or exchanges to the thermal dissipation device 230 via the extension 250A.

In some environmental conditions, condensation forms on the thermal dissipation device 230 and in particular at the extension 250B. This condensation is collected at the fluid dispenser 240. In one embodiment, the fluid dispenser 240 includes a collector 270 and an ejector 272. The collector 270 collects dew or water vapor forming on the extensions. The water is transferred via a fluid line 274 to the ejector 272.

The ejector 272 atomizes or vaporizes the water and propels it toward the thermal dissipation device. In one embodiment, an airflow (shown with arrow 280) channels the ejected vapor to and past the thermal dissipation device 230.

As the vapor passes the thermal dissipation device 230, heat is transferred from the thermal dissipation device 230 to the moisture in the vapor. In one embodiment, the moist and now heated air is evacuated from the system. In another embodiment, the moist and heated air is cooled and re-cycled into the system to provide moisture for more condensation for the system.

Heat exchange in the system 200 occurs as follows. Heat generated from the heat generating devices 210 transfers to the extensions 250A, 250B. In turn, the extensions produce condensation that is collected in the fluid dispenser 240. Heat collected at the extensions transfers from a first end 290 of the thermal dissipation device 230 to a second, opposite end 292. The collected fluid is vaporized and forced past the second end 292. Here, heat at the second end 292 transfers to the vapor which is then removed from the system or cooled and circulated back through the system.

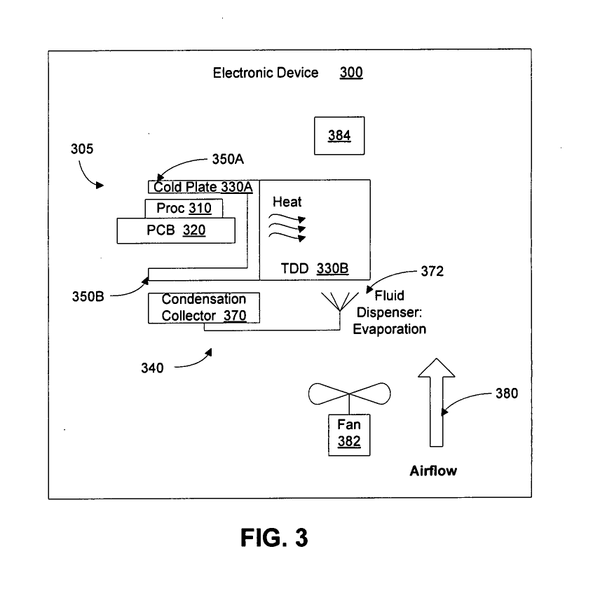

FIG. 3 shows an electronic device 300 in accordance with an exemplary embodiment. The electronic device 300 includes a system 305 for cooling heat generating components. In one embodiment, the system 305 includes one or more components of the system 200 discussed in connection with FIGS. 2A and 2B, with some differences being noted.

The system 305 generally includes plural heat generating components 310 (shown as processors with label proc), a printed circuit board 320 (shown as PCB), a first thermal dissipation device 330A (shown as a cold plate), a second thermal dissipation device 330B (shown as TDD), and a fluid dispenser 340 that includes a condensation collector 370 and a fluid emitter 372.

In one embodiment, the thermal dissipation device 330B includes an electrical device that cools at least part of cold plate 330A and/or processors 310 to a temperature that is at or below ambient or surrounding temperature in the electronic device 300. Heat from the processors 310 transfers or exchanges to the cold plate 330A via the extension 350A.

In some environmental conditions, condensation forms on the cold plate 330A. This condensation is collected at the condensation collector or reservoir 370. The collector 370 collects dew or water vapor forming on the extensions. The water is transferred to the fluid emitter 372.

The fluid emitter 372 atomizes or vaporizes the water and propels it toward the thermal dissipation device 330B. In one embodiment, an airflow (shown with arrow 380) is generated from a fan 382. The airflow causes the ejected vapor to pass across a surface of the thermal dissipation device 330B.

As the vapor passes the thermal dissipation device 330B, heat is transferred from the thermal dissipation device 330B to the moisture in the vapor. In one embodiment, the moist and now heated air is evacuated from the electronic device 300 (example, through a opening or exit 384 in a chassis or housing of the electronic device).

Heat exchange in the system 305 occurs as follows. Heat generated from the processors 310 transfers to the cold plate 330A. In turn, the cold plate produces condensation that is collected in the condensation collector 370. Heat collected at the cold plate 330A transfers to the thermal dissipation device 330B. The collected fluid is vaporized and directed over a surface of the thermal dissipation device 330B. Here, heat transfers to the vapor which is evacuated through exit 384.

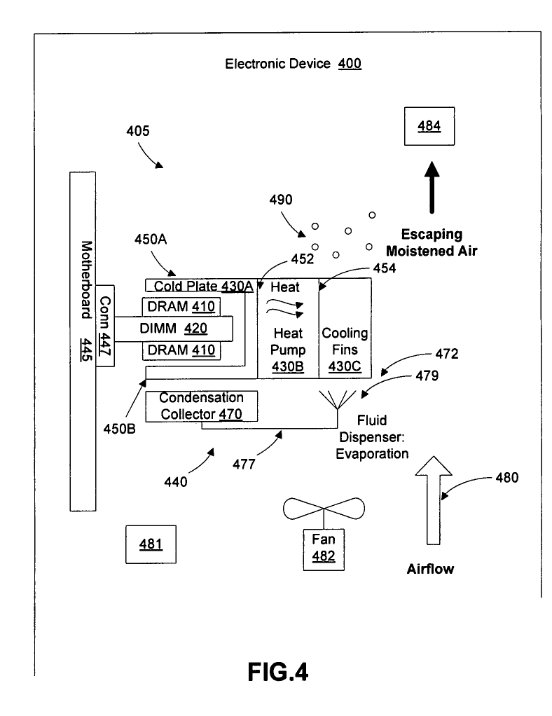

FIG. 4 shows an electronic device 400 in accordance with an exemplary embodiment. The electronic device 400 includes a system 405 for cooling heat generating components. In one embodiment, the system 405 includes one or more components of the system 200 discussed in connection with FIGS. 2A and 2B, with some differences being noted.

The system 405 generally includes plural heat generating components 410 (shown as plural DRAM: dynamic random access memory), a first printed circuit board 420 (shown as DIMM: dual in-line memory module), a first thermal dissipation device 430A (shown as a cold plate or heat spreader), a second thermal dissipation device 430B (shown as heat pump), a third thermal dissipation device 430C (shown as cooling fins), a fluid dispenser 440 that includes a condensation collector 470 and a fluid ejector 472, and second printed circuit board 445 (shown as a motherboard) connected to the DIMM 410 via a connector 447.

In one embodiment, the heat pump 430B includes an electrical device that cools extensions 450A, 450B and/or DRAMs 410 to a temperature that is at or below ambient or surrounding temperature of the electronic device 400. A cool side 452 of the heat pump 430B attaches or couples to the cold plate 430A. A hot side 454 of the heat pump 430B attaches or couples to the cooling fins 430C. Heat from the DRAMs 410 transfers or exchanges to the cold plate 430A via the extensions 450A, 450B.

Condensation forms on the cold plate 430A. This condensation is collected at the condensation collector or reservoir 470. In one embodiment, the collector includes a tray, a wick, or capillary system. The collector 470 collects dew or water vapor forming on the extensions. The water is transferred (example, via a capillary system 477) to the fluid ejector 472. In one embodiment, the fluid ejector includes a spray nozzle 479. The spray nozzle 479 sprays the condensation water on the hot side 454 of the heat pump 430B and, in particular, at the cooling fins 430C.

In one embodiment, a microcontroller 481 controls the temperature of the DIMMs 420 and current through the heat pump 430B. The microcontroller 481 also measures the amount of condensation and operates the spray nozzle 479.

The fluid ejector 472 atomizes or vaporizes the water and propels it toward the cooling fins 430C. In one embodiment, an airflow (shown with arrow 480) is generated from a fan 482 which blows air across the cooling fins 430C. The airflow causes the ejected vapor to pass across a surface of the cooling fins 430C.

As the vapor passes the cooling fins 430C, heat is transferred from the cooling fins 430C to the moisture in the vapor. The moisture in the air added from the vaporized condensation increases the thermal capacity of the air to remove heat from the cooling fins. As such, more heat is able to be conducted out of the electronic device. In one embodiment, the moist and now heated air 490 is evacuated from the electronic device 400 (example, through a opening or exit 484 in a chassis or housing of the electronic device).

Heat exchange in the system 405 occurs as follows. Heat generated from the DRAMs 410 transfers to the cold plate 430A. In turn, the cold plate produces condensation that is collected in the condensation collector 470. Heat collected at the cold plate 430A transfers, via the heat pump 430B, to the cooling fins 430C. The collected fluid is vaporized and directed past or over a surface of the cooling fins 430C. Here, heat transfers to the vapor which is evacuated through exit 484.

The printed circuit boards (PCBs) in exemplary embodiments can have a variety of configurations. By way of example, the PCBs include one or more of a motherboard, a daughter board, power module circuit boards, memory boards, voltage regulation module (VRM) circuit boards, controller boards (such as a special type of expansion board that contains a controller for a peripheral device), and/or expansion boards (such as any board that plugs into an expansion slot of a computer), to name a few examples.

A motherboard is a printed circuit board that can be used in a personal computer, server, or other electronic device. The motherboard (also known as a main board or system board) provides attachment points for processors, graphics cards, sound cards, controllers, memory, integrated circuits (ICs), modules, PCBs, and many other electronic components and devices in a computing system.

Connectors 447, for example, are used to electrically couple the motherboard 445 to the DIMMs 420. Connectors 447 provide a mechanical and electrical interface or connection between PCBs and include, for example, a removably connectable plug (male) and socket (female).

In one exemplary embodiment, PCBs include one of more of a plurality of heat generating components or devices. These heat generating components include any electronic component that generates heat during operation. For example, heat-generating devices include, but are not limited to, memory, electronic power circuits, integrated circuits (ICs) or chips, digital memory chips, application specific integrated circuits (ASICs), processors (such as a central processing unit (CPU) or digital signal processor (DSP)), discrete electronic devices (such as field effect transistors (FETs)), other types of transistors, or devices that require heat to be thermally dissipated from the device for the device to operate properly or within a specified temperature range. An ASIC can comprise an integrated circuit or chip that has functionality customized for a particular purpose or application. Further, a PCB can include a plurality of electronic components or device that may or may not generate heat, that may generate low or insignificant amounts of heat, or that may generate heat but not require the generated heat to be thermally dissipated from the device for the device to operate properly or within a specified temperature range. Examples of such devices include, but are not limited to, resistors, capacitors, transistors, diodes, memories, etc.

In one exemplary embodiment, the electronic device or electronic system includes at least one thermal dissipation device. Thermal dissipation devices include, but are not limited to, heat spreaders, cold plates or thermal-stiffener plates, refrigeration (evaporative cooling) plates, heat pipes, mechanical gap fillers (such as a plurality of rods, pins, etc.), thermal pads, or other devices adapted to dissipate heat. Further, thermal dissipation devices include thermal compounds and thermal interface material that can be used to form a thermally conductive layer on a substrate, between electronic components, or within a finished component. For example, thermally conductive resins, tapes, molded thermoplastic compounds, adhesives, gap pads, and greases can be used between a heat-generating device and thermal dissipating device to improve heat dissipation and/or heat transfer. Further, thermal dissipation devices include heatsinks. A heatsink is a component designed to reduce the temperature of a heat-generating device or component. A heatsink, for example, can dissipate heat in a direct or indirect heat exchange with the electronic components, the heat being dissipated into surrounding air or surrounding environment. Numerous types of heatsinks can be utilized with exemplary embodiments. For example, embodiments include heatsinks without a fan (passive heatsinks) or heatsinks with a fan (active heatsink). Other examples of heatsinks include extruded heatsinks, folded fin heatsinks, cold-forged heatsinks, bonded/fabricated heatsinks, and skived fin heatsinks. Further, the thermal dissipation device, including heatsinks, can use liquids or phase change material. For example, the thermal dissipation device can conduct heat from heat-generating devices to a heatsink that is liquid or air cooled. Furthermore, liquid pipes or liquid loops can be used to evacuate or transfer heat from the thermal dissipation device or module to an external location that is remote from the thermal dissipation device or module.

As used herein, the term “DRAM” is memory that stores bits of data in capacitors in an integrated circuit. As used herein, the term “DIMM” is a series of random access memory integrated circuits as modules that are mounted on a printed circuit board.

The methods in accordance with exemplary embodiments are provided as examples and should not be construed to limit other embodiments within the scope of the invention. For instance, blocks in diagrams or numbers (such as (1), (2), etc.) should not be construed as steps that must proceed in a particular order. Additional blocks/steps may be added, some blocks/steps removed, or the order of the blocks/steps altered and still be within the scope of exemplary embodiments. Further, methods or steps discussed within different figures can be added to or exchanged with methods of steps in other figures. Further yet, specific numerical data values (such as specific quantities, numbers, categories, etc.) or other specific information should be interpreted as illustrative for discussing exemplary embodiments.

Exemplary embodiments and steps associated therewith can be implemented as one or more computer software programs to implement the methods described herein. The software is implemented as one or more modules (also referred to as code subroutines, or “objects” in object-oriented programming). The location of the software will differ for the various alternative embodiments. The software programming code, for example, is accessed by a processor or processors of the computer or server from long-term storage media of some type, such as a CD-ROM drive or hard drive. The software programming code is embodied or stored on any of a variety of known media for use with a data processing system or in any memory device such as semiconductor, magnetic and optical devices, including a disk, hard drive, CD-ROM, ROM, etc. The code is distributed on such media, or is distributed to users from the memory or storage of one computer system over a network of some type to other computer systems for use by users of such other systems. Alternatively, the programming code is embodied in the memory and accessed by the processor using the bus. The techniques and methods for embodying software programming code in memory, on physical media, and/or distributing software code via networks are well known and will not be further discussed herein.

While the exemplary embodiments have been disclosed with respect to a limited number of embodiments, those skilled in the art will appreciate, upon reading this disclosure, numerous modifications and variations. It is intended that the appended claims cover such modifications and variations.

What is claimed is:

1) A method, comprising:
cooling a heat generating component in an electronic device below an ambient temperature to produce condensation;
transferring heat from the heat generating component to a thermal dissipation device;
dispensing the condensation onto a thermal dissipation device to cool the thermal dissipation device.

2) The method of claim 1 further comprising:
vaporizing the condensation;
blowing vaporized condensation across the thermal dissipation device.

3) The method of claim 1 further comprising:
collecting the condensation;
spraying collected condensation across the thermal dissipation device.

4) The method of claim 1 further comprising, evacuating the condensation through an opening in the electronic device.

5) The method of claim 1 further comprising, transferring heat from the thermal dissipation device to the condensation.

6) The method of claim 1 further comprising:
spraying the condensation on the thermal dissipation device;
evaporating the condensation on the thermal dissipation device to cool the thermal dissipation device.

7) An electronic device, comprising:
a printed circuit board (PCB);
a heat generating device mounted to the PCB;
a cooling device that cools the heat generating device below an ambient temperature in the electronic device to produce condensation;
a fluid dispenser that emits the condensation onto a thermal dissipation device to cool the thermal dissipation device.

8) The electronic device of claim 7, wherein the heat generating device is dynamic random access memory, DRAM.

9) The electronic device of claim 7 further comprising, a cold plate having a first extension that extends adjacent a first side of the PCB and a second extension that extends adjacent a second side of the PCB.

10) The electronic device of claim 7, wherein the fluid dispenser includes a nozzle that vaporizes the condensation onto the thermal dissipation device.

11) The electronic device of claim 7, wherein the fluid dispenser includes a condensation collector that collects the condensation.

12) The electronic device of claim 7 further comprising, a heat pump that cools the cooling device and transfers heat from the cooling device to the thermal dissipation device.

13) The electronic device of claim 7 further comprising, a fan that blows vaporized condensation across fins on the thermal dissipation device.

14) The electronic device of claim 7 further comprising, an exit for evacuating vaporized condensation from the electronic device.

15) A method, comprising:
cooling heat generating components on a printed circuit board (PCB) in an electronic device to create condensation;
collecting the condensation;
directing collected condensation to a thermal dissipation device to transfer heat from the thermal dissipation device to the collected condensation.

16) The method of claim 15 further comprising:
spraying the collected condensation onto the thermal dissipation device;
evaporating the collected condensation with heat of the thermal dissipation device.

17) The method of claim 15, wherein the heat generating components include at least one processor on the PCB.

18) The method of claim 15 further comprising:
contacting the heat generating components with a cold plate;
forming the condensation on the cold plate.

19) The method of claim 15 further comprising, cooling the heat generating components to a temperature that is below ambient temperature.

20) The method of claim 15 further comprising:
cooling the heat generating components with a heat pump;
vaporizing the collected condensation onto fins of the thermal dissipation device.
